(19) United States
(12) Patent Application Publication
(10) Pub. No.: US 2016/0381784 A1
(43) Pub. Date: Dec. 29, 2016

(54) COMMUNICATION MODULE AND METHOD OF MANUFACTURING COMMUNICATION MODULE

(71) Applicant: ALPS ELECTRIC CO., LTD., Tokyo (JP)

(72) Inventor: Ken MIURA, Miyagi-ken (JP)

(21) Appl. No.: 15/171,921

(22) Filed: Jun. 2, 2016

(30) Foreign Application Priority Data
Jun. 26, 2015 (JP) 2015-128556

(51) Int. Cl. H05K 1/02; H05K 3/30; H01Q 1/50; H01Q 1/38

(52) U.S. Cl. CPC H05K 1/025; H01Q 1/38; H05K 1/0243; H05K 3/30; H01Q 1/50; H05K 2201/055; H05K 2201/10098; H05K 2203/1316

(57) ABSTRACT

A communication module includes a flexible board having a first region, a second region, and a third region located between the first region and the second region, a communication circuit including a communication electronic component mounted on one surface of the first region, an antenna dielectric mounted on a portion of one surface of the second region, a matching circuit including a matching electronic component mounted on another portion of the one surface of the second region, and an antenna including a metal pattern formed in the other surface of the second region, the matching circuit matches the antenna with the communication circuit, the communication circuit is sealed with a resin, the third region is folded, and the resin and the antenna dielectric are brought into contact with each other.

### CLAIM OF PRIORITY

This application claims benefit of Japanese Patent Application No. 2015-128556 filed on Jun. 26, 2015, which is hereby incorporated by reference.

### BACKGROUND OF THE INVENTION

1. Field of the Invention

The present invention relates to a communication module in which a communication circuit and an antenna are formed on a board, and a method of manufacturing the communication module.

2. Description of the Related Art

Conventionally, an electronic circuit module in which a communication circuit having a plurality of electronic components and an antenna are provided on one board has been commercialized. However, in a case in which the plurality of electronic components and the antenna are provided on one board, a circuit formation area on the board greatly increases, and a size of an electronic circuit device increases. To solve this problem, a structure of an electronic circuit module in which electronic components are mounted on two boards, the two boards face each other, and the two boards are connected by a flexible cable such that a size of the module is prevented from increasing has been proposed.

As this type of electronic circuit module, an invention of an electronic circuit device described in Japanese Unexamined Patent Application Publication No. 2003-158356 is disclosed. An electronic circuit device 900 described in Japanese Unexamined Patent Application Publication No. 2003-158356 is illustrated in FIG. 8.

This electronic circuit device 900 includes a plurality of circuit boards 903 and 904 having electronic components 902a to 902g mounted thereon, a flexible cable 905 integrally formed in the circuit boards 903 and 904, extending from end surfaces of the respective boards, and electrically connecting the respective boards to each other, and a spacer 906 that holds the respective boards in a state in which the respective boards face each other.

In this electronic circuit device 900 configured as above, the electrical connection between the circuit boards 903 and 904 is performed by the flexible cable 905, and the respective boards are held by the spacer 906 in a state in which the respective boards face each other. Thus, since a function of mechanical connection and relative positioning of the respective boards and a function of the electrical connection between the respective boards are separated from each other, a size (particularly, a thickness) of the spacer 906 which performs the former can be reduced (narrowed) to the minimal extent necessary for the relative positioning between the circuit boards 903 and 904. This can reduce an area occupied by the spacer 906 in each of the boards. Further, since the electrical connection between the circuit boards 903 and 904 is performed by the flexible cable 905, it is unnecessary to secure the electrical connection in an assembly process, and the assembly process can be facilitated.

However, in the electronic circuit device 900, there are the following problems. The electronic circuit device 900 has a structure in which the circuit boards 903 and 904 are held by the spacer 906 in a state in which the circuit boards 903 and 904 face each other, but in a case in which the thickness of the spacer 906 is decreased to further miniaturize the electronic circuit device 900, there is a problem in which stress is applied to the spacer 906, and the spacer 906 and the electronic circuit device 900 are damaged. Conversely, in a case in which the thickness of the spacer 906 is increased so that the electronic circuit device 900 is not damaged, there is a problem in which that the electronic circuit device 900 cannot be miniaturized.

### SUMMARY OF THE INVENTION

The present invention provides a communication module that is not damaged even when miniaturized, and a method of manufacturing the communication module.

To solve this problem, the communication module of the present invention includes: a flexible board having a first region, a second region, and a third region located between the first region and the second region, a communication circuit including a communication electronic component mounted on one surface of the first region, an antenna dielectric mounted on a portion of one surface of the second region, a matching circuit including a matching electronic component mounted on another portion of the one surface of the second region, and an antenna including a metal pattern formed in the other surface of the second region, wherein the matching circuit is a circuit for matching the antenna with the communication circuit, the communication circuit being sealed with a resin, and the third region is folded and the resin and the antenna dielectric are brought into contact with each other.

In the communication module configured as above, since the antenna dielectric mounted on the one surface of the second region of the flexible board is supported by the resin covering the communication circuit configured on the one surface of the first region of the flexible board, a spacer is not necessary, and the communication module is not damaged even when the communication module is miniaturized.

Further, in the above configuration, the resin and the antenna dielectric are adhered to each other by an adhesive.

In the communication module configured as above, since the resin with a wide area on the first region and the antenna dielectric with a relatively wide area on the second region are adhered such that the first region and the second region are adhered over a wide area, it becomes difficult for the first region and the second region of the flexible board to be peeled.

Further, in the above configuration, an outer shape is a rectangular parallelepiped shape, all of the surfaces constituting the rectangular parallelepiped are covered with the flexible board, and a ground pattern is formed on all of the side surfaces of the rectangular parallelepiped.

In the communication module configured as above, since the outer shape is a rectangular parallelepiped, all of the surfaces constituting the rectangular parallelepiped are covered with the flexible board, and the ground pattern is formed on all of the side surfaces of the rectangular parallelepiped, it is possible to enhance a shielding effect of the communication circuit and the matching circuit.

Further, in order to solve this problem, a method of manufacturing a communication module of the present invention includes: a first process of mounting a communication electronic component constituting a communication circuit on one surface of a first region of a flexible board having the first region and a second region, and a third region located between the first region and the second region, and mounting an antenna dielectric and a matching electronic component on one surface of the second region; a second process of sealing the communication circuit with a resin; and a third process of bending the third region, bringing the resin into contact with the antenna dielectric, and adhering the resin to the antenna dielectric.

In the method of manufacturing the communication module configured as above, since the communication module is manufactured so that the antenna dielectric mounted on the one surface of the second region of the flexible board is supported by the resin covering the communication circuit configured on the one surface of the first region of the flexible board, a spacer is not necessary, and the communication module is not damaged even when the communication module is miniaturized.

In the communication module of the present invention, since the antenna dielectric mounted on the one surface of the second region of the flexible board is supported by the resin covering the communication circuit configured on the one surface of the first region of the flexible board, a spacer is not necessary, and the communication module is not damaged even when the communication module is miniaturized. Further, in the method of manufacturing the communication module of the present invention, since the second region of the flexible board is supported by the resin covering the communication circuit configured on the one surface of the first region of the flexible board, a spacer is not necessary, and the communication module is not damaged even when the communication module is miniaturized.

### BRIEF DESCRIPTION OF THE DRAWINGS

FIG. 1 is a perspective view of a communication module of a first embodiment of the present invention.

FIG. 2 is a side view of the communication module of the first embodiment.

FIG. 3 is a plan view of the communication module of the first embodiment.

FIGS. 4A though 4C are side views illustrating a method of manufacturing a communication module of the first embodiment.

FIGS. 5A and 5B are plan views illustrating the method of manufacturing a communication module of the first embodiment.

FIG. 6 is a perspective view of a communication module of a second embodiment of the present invention.

FIG. 7 is a plan view of the communication module of the second embodiment during a manufacturing process.

FIG. 8 is a side view of the communication module according to an example of the related art.

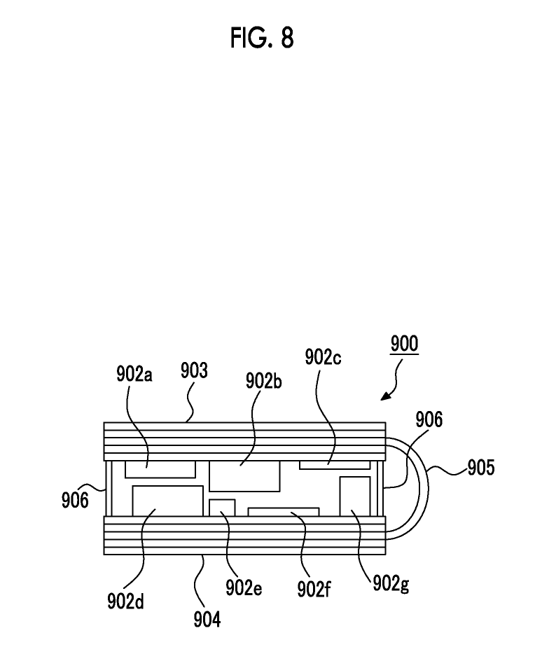

### DESCRIPTION OF THE PREFERRED EMBODIMENTS

Hereinafter, embodiments of the present invention will be described with reference to the drawings. In this specification, an X1 side in each drawing is a right side, an X2 side is a left side, a Y1 side is a back side, a Y2 side is a front side, a Z1 side is an upper side, and a Z2 side is a lower side, unless otherwise mentioned.

### First Embodiment

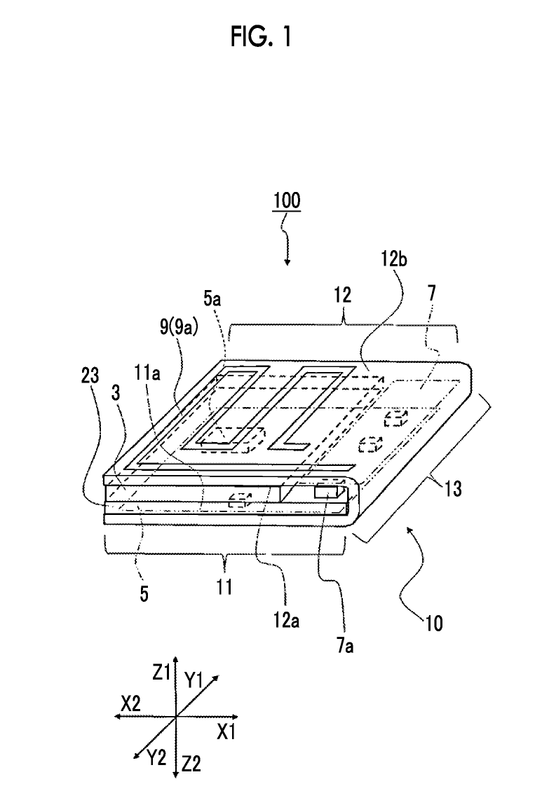

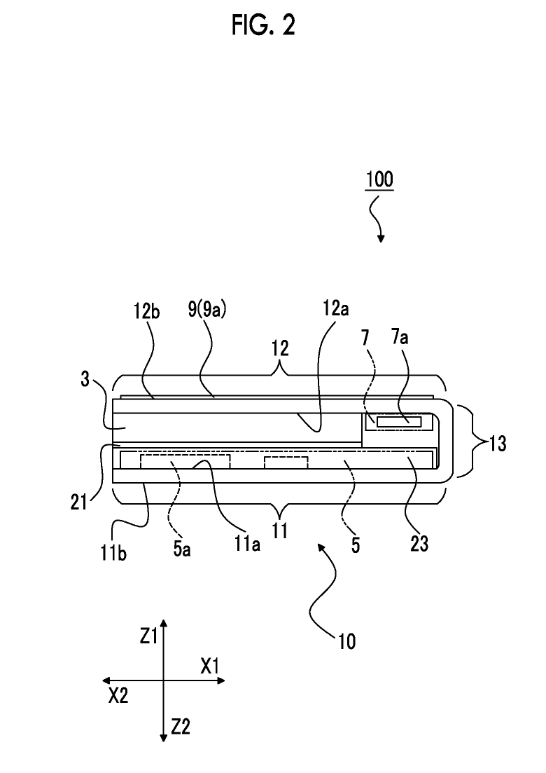

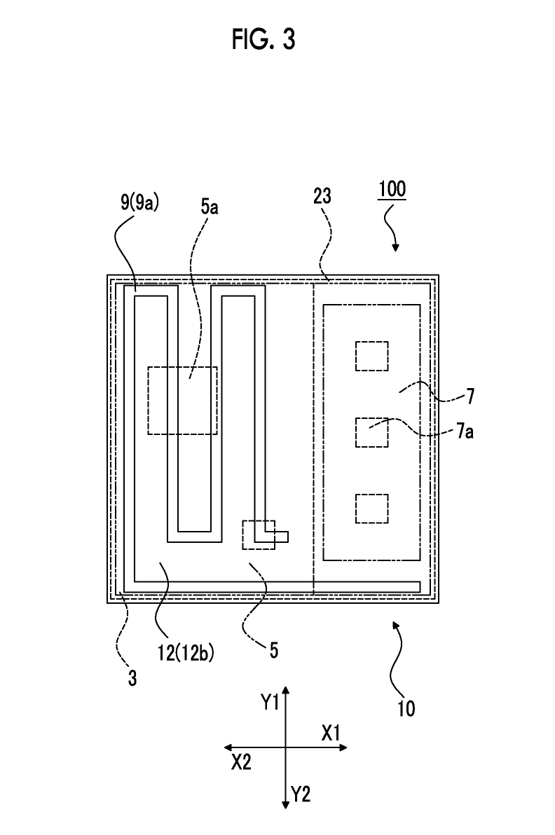

First, a communication module 100 in a first embodiment of the present invention will be described. The communication module 100 in the first embodiment of the present invention is illustrated in FIGS. 1 to 3. FIG. 1 is a perspective view of the communication module 100 of the present invention. Further, FIG. 2 is a side view of the communication module 100, and FIG. 3 is a plan view of the communication module 100.

As illustrated in FIGS. 1 and 3, the communication module 100 has a rectangular shape in a plan view, and includes a flexible board 10, a communication circuit 5 including a communication electronic component 5a mounted on the flexible board 10, a matching circuit 7 including matching electronic component 7a mounted on the flexible board 10, an antenna dielectric 3, and an antenna 9 formed in the flexible board 10.

The communication module 100 is mounted on a small high-frequency device which is, for example, a mobile device such as a wearable terminal device, and is configured such that the communication module 100 can communicate with another terminal device such as a smartphone using the antenna 9 and the communication circuit 5.

The flexible board 10 includes a first region 11, a second region 12, and a third region 13 located between the first region 11 and the second region 12. The flexible board 10 is a rigid flexible board having a rectangular shape, and has flexibility.

The communication electronic component 5a constituting the communication circuit 5 is mounted on one surface 11a (an upper surface illustrated in FIG. 2) of the first region 11 of the flexible board 10, as illustrated in FIGS. 1 and 2. The communication electronic component 5a is a plurality of electronic components such as integrated circuits or resistors for communication with another terminal device using the antenna 9. Further, the plurality of communication electronic components 5a are connected to one another by a conductive line (not illustrated) or a ground pattern (not illustrated) over substantially the entire region of the one surface 11a of the first region 11, such that the communication circuit 5 includes the conductor line and the ground pattern, in addition to the communication electronic components 5a. The communication circuit 5 is connected to the antenna 9 via the matching circuit 7.

Although the conductor line or the ground pattern is formed in the one surface 11 a in the first region 11 of the flexible board 10 in the present embodiment, the conductor line or the ground pattern may be formed in an inner layer of the first region 11 of the flexible board 10.

The entire communication circuit 5 configured in the first region 11 is sealed by a resin 23. Accordingly, the resin 23 for sealing the communication circuit 5 is formed over substantially the entire region of the one surface 11a in the first region 11 of the flexible board 10 and occupies substantially the same wide area as the communication module 100 in a plan view, as illustrated in FIGS. 2 and 3. The resin 23 is a thermosetting resin.

As illustrated in FIGS. 1 and 2, the antenna dielectric 3 is mounted in a portion (a left portion illustrated in FIG. 2) of one surface 12a (a lower surface illustrated in FIG. 2) of the second region 12 of the flexible board 10 by soldering or the like. The antenna dielectric 3 occupies a relatively wide area on the one surface 12a of the second region 12 of the flexible board 10. Further, the matching electronic component 7a constituting the matching circuit 7 is mounted in another portion (a right portion illustrated in FIG. 2 in which the antenna dielectric 3 is not mounted) of the one surface 12a (the lower surface illustrated in FIG. 2) of the second region 12 of the flexible board 10 by soldering or the like.

The antenna 9 is formed on the other surface 12b (an upper surface illustrated in FIG. 2) of the second region 12 of the flexible board 10, as illustrated in FIGS. 1 to 3. The antenna 9 is formed of a printed conductor, which is made of a metal pattern 9a. By arranging the antenna 9 on the other surface 12b of the second region 12, that is, the upper surface of the communication module 100, it is possible to provide the antenna 9 so that the antenna 9 comes in direct contact with an outer space of the communication module 100. Therefore, it is possible to prevent characteristics of the antenna 9 from degrading in comparison with a case in which the antenna 9 is arranged on the inner side of the folded flexible board 10.

Although the antenna 9 in the communication module 100 of the present embodiment is formed of the printed conductor on the flexible board 10, the antenna 9 may be a type of chip antenna placed on and attached to the other surface 12b of the second region 12 of the flexible board 10. Further, although the antenna 9 is a monopole antenna having a meandering shape in this embodiment, the antenna 9 may be an antenna having another form such as inverted-F type antenna.

The antenna dielectric 3 has an effect of shortening a wavelength of a high-frequency signal. Therefore, by forming the antenna 9 on the other surface 12b of the second region 12 of the flexible board 10 and mounting the antenna dielectric 3 on the one surface 12a of the second region 12 of the flexible board 10, it is possible to shorten a length of the metal pattern 9a of the antenna 9 while maintaining a resonant frequency. As a result, it is possible to miniaturize the communication module 100.

The matching circuit 7 is a circuit for matching impedance of the antenna 9 with impedance of the communication circuit 5. The matching electronic component 7a constituting the matching circuit 7 usually includes a plurality of circuit elements such as capacitors and inductors. An individual electronic component may be used as the inductor, but the inductor may be realized by a transmission line made of a printed conductor. Capacitance between transmission lines made of printed conductors may be used as the capacitor. With these components, it is possible to further miniaturize the communication module 100. The matching circuit 7 also includes a conductor line and a ground pattern, in addition to the matching electronic component 7a. The matching circuit 7 and the communication circuit 5 are connected to each other by a transmission line on the flexible board 10, and the matching circuit 7 and the antenna 9 are connected to each other by a through-hole (not illustrated) formed in the second region 12 of the flexible board 10.

The third region 13 of the flexible board 10 is located between the first region 11 and the second region 12. As illustrated in FIGS. 1 and 2, the communication module 100 has a structure in which the third region 13 is folded and the one surface 11a of the first region 11 and the one surface 12a of the second region 12 face each other. Therefore, the resin 23 formed on the one surface 11a of the first region 11 and the antenna dielectric 3 mounted on the one surface 12a of the second region 12 come into contact with each other. The resin 23 formed on the one surface 11a of the first region 11 and the antenna dielectric 3 mounted on the one surface 12a of the second region 12 are adhered and fixed to each other by adhesive 21, as illustrated in FIG. 2.

The resin 23 formed on the one surface 11a of the first region 11 and the antenna dielectric 3 mounted on the one surface 12a of the second region 12 occupy a greater area in a plan view within the one surface 11a of the first region 11 or the one surface 12a of the second region 12. Therefore, the first region 11 and the second region 12 are adhered to each other over a wide area. As a result, it is possible to firmly adhere the resin 23 to the antenna dielectric 3.

On the other surface 11b of the first region 11 which is a surface opposite to the one surface 11a of the first region 11 illustrated in FIG. 2, a conductor is formed and a plurality of connection terminals (not illustrated) connected to the communication circuit 5 by through-holes (not illustrated) are provided, such that an electronic device such as a mobile device on which the communication module 100 is mounted can be connected to the communication circuit 5 in the communication module 100.

Embodiment of method of manufacturing communication module

Next, a method of manufacturing the communication module 100 will be described with reference to FIGS. 3 to 5.

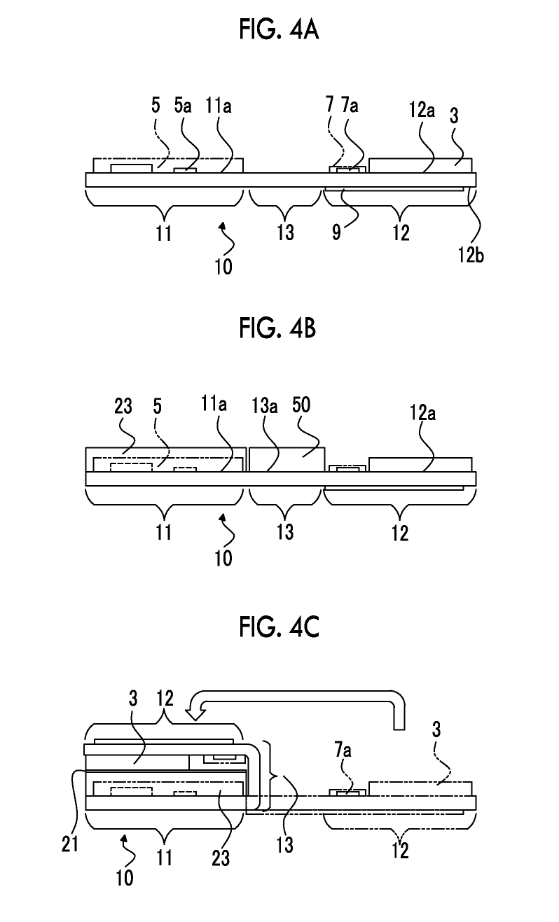

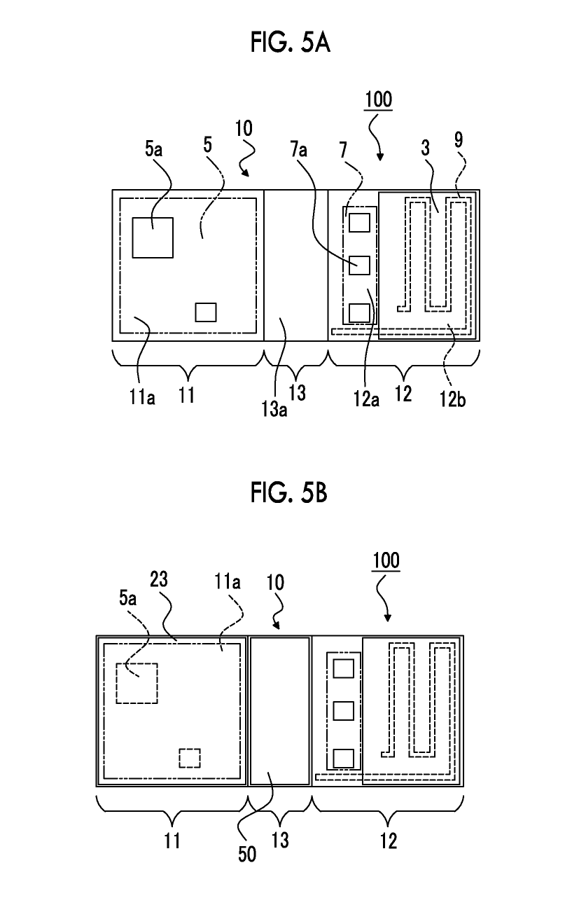

FIGS. 4A to 4C are side views illustrating a method of manufacturing the communication module 100. FIG. 4A illustrates a first process of the method of manufacturing the communication module 100, FIG. 4B illustrates a second process of the method of manufacturing the communication module 100, and FIG. 4C illustrates a third process of the method of manufacturing the communication module 100. FIGS. 5A and 5B are plan views illustrating the method of manufacturing the communication module 100. FIG. 5A illustrates the communication module 100 after the first process, and FIG. 5B illustrates the communication module 100 after the second process. A plan view of the communication module 100 after the third process is as illustrated in FIG. 3.

In the method of manufacturing the communication module 100, the flexible board 10 is first prepared. The flexible board 10 includes the first region 11, the second region 12, and the third region 13 located between the first region 11 and the second region 12, as illustrated in FIG. 4A. The antenna 9 including the metal pattern 9a has already been formed in the other surface 12b (a lower surface illustrated in FIG. 4A) of the second region 12 of the flexible board 10 by printing.

In the first process of the method of manufacturing the communication module 100 illustrated in FIG. 4A, the communication electronic component 5a constituting the communication circuit 5 is mounted on the one surface 11a (an upper surface of illustrated in FIG. 4A) of the first region 11 of the flexible board 10. That is, the communication electronic component 5a, including an integrated circuit, a resistor, and the like, is placed at a predetermined position on the one surface 11a of the first region 11, and then, the communication electronic component 5a is attached to a conductor electrode (not illustrated) provided in the one surface 11a of the first region 11 by soldering or the like.

In the first process of the method of manufacturing the communication module 100, the matching electronic component 7a constituting the matching circuit 7 and the antenna dielectric 3 are mounted on the one surface 12a (an upper surface illustrated in FIG. 4A) of the second region 12 of the flexible board 10, simultaneously with the communication electronic component 5a being mounted as illustrated in FIG. 4A. That is, the matching electronic component 7a, including a capacitor or an inductor, and the antenna dielectric 3 are placed at predetermined positions on the one surface 12a of the second region 12, and then, such a plurality of components are attached to a conductor electrode (not illustrated) provided on the one surface 12a of the second region 12 by soldering or the like.

If the communication module 100 after the first process of the method of manufacturing the communication module 100 is viewed from the top, it can be seen that the communication electronic component 5a constituting the communication circuit 5 is mounted on the one surface 11a of the first region 11 of the flexible board 10, as illustrated in FIG. 5A. Further, it can be seen that the matching electronic component 7a constituting the matching circuit 7 and the antenna dielectric 3 are mounted on the one surface 12a of the second region 12 of the flexible board 10. The antenna 9 is on the other surface 12b side (a back side) of the second region 12 in the flexible board 10.

A second process of the method of manufacturing the communication module 100 illustrated in FIG. 4B is a process of sealing the communication circuit 5 including the communication electronic components 5a mounted on the one surface 11a of the first region 11 of the flexible board 10, and the conductor line formed in the one surface 11a of the first region 11 and connecting the plurality of communication electronic components 5a, with the resin 23. The resin 23 is injected into only the one surface 11a of the first region 11 including the communication electronic component 5a of the flexible board 10 at least at a height of the communication electronic component 5a. The injected resin 23 is cured by applied heat to seal the communication circuit 5.

When the communication circuit 5 is sealed with the resin 23, a mold 50 is placed on one surface 13a (an upper surface illustrated in FIG. 4B) of the third region 13 of the flexible board 10 on which no component is mounted. By placing the mold 50, it is possible to prevent the resin 23 from being injected into each of the one surface 12a of the second region 12 and one surface 13a of the third region 13 of the flexible board 10. The mold 50 is removed after the communication circuit 5 is sealed with the resin 23.

When the communication module 100 after the second process of the method of manufacturing the communication module 100 is viewed from the top, it can be seen that the communication circuit 5 including the communication electronic components 5a mounted on the one surface 11a of the first region 11 of the flexible board 10 is covered with the resin 23 to a boundary line with the third region 13 in which there is the mold 50, as illustrated in FIG. 5B.

The third process of the method of manufacturing the communication module 100 illustrated in FIG. 4C is a process of bending the third region 13 located between the first region 11 and the second region 12 of the flexible board 10, bringing the resin 23 mounted in the first region 11 into contact with the antenna dielectric 3 mounted in the second region 12, and adhering the resin 23 to the antenna dielectric 3.

In a state in which the matching electronic component 7a and the antenna dielectric 3 are mounted in the second region 12 of the flexible board 10, the third region 13 is folded at a boundary line between the first region 11 and the third region 13, the third region 13 is then bent, the third region 13 is further folded at a boundary line between the second region 12 and the third region 13, and the resin 23 mounted in the first region 11 is brought into contact with the antenna dielectric 3 mounted in the second region 12.

The adhesive 21 is applied to a lower surface of the antenna dielectric 3 or an upper surface of the resin 23 illustrated in FIG. 4C, and the antenna dielectric 3 and the resin 23 are pressed and brought into contact with each other. Accordingly, the antenna dielectric 3 and the resin 23 are strongly adhered and fixed to each other by the adhesive 21. Thereafter, the communication module 100 is set up, as illustrated in FIG. 3.

Through the respective processes of the method of manufacturing the communication module 100 illustrated in FIGS. 4A to 4C, it is possible to manufacture the communication module 100.

Thus, in the method of manufacturing the communication module 100, the antenna dielectric 3 mounted on the one surface 12a of the second region 12 is firmly supported by the resin 23 covering the communication circuit 5 including the communication electronic component 5a mounted on the one surface 11a of the first region 11 of the flexible board 10.

### Second Embodiment

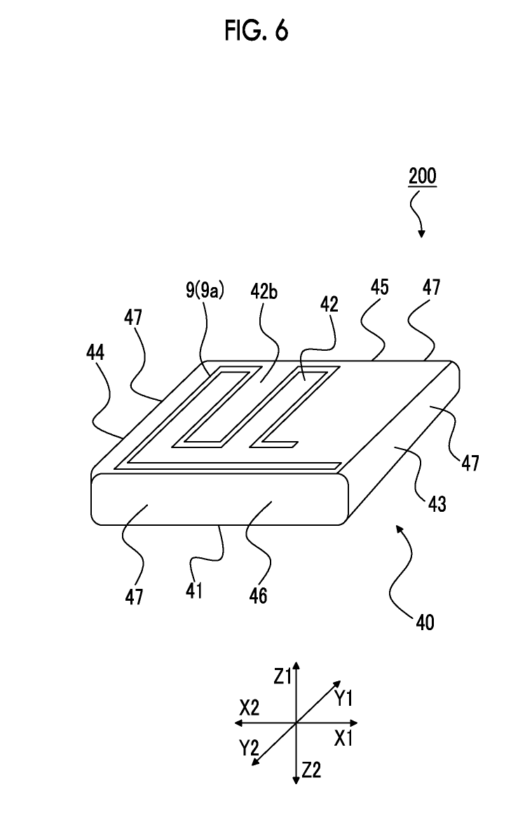

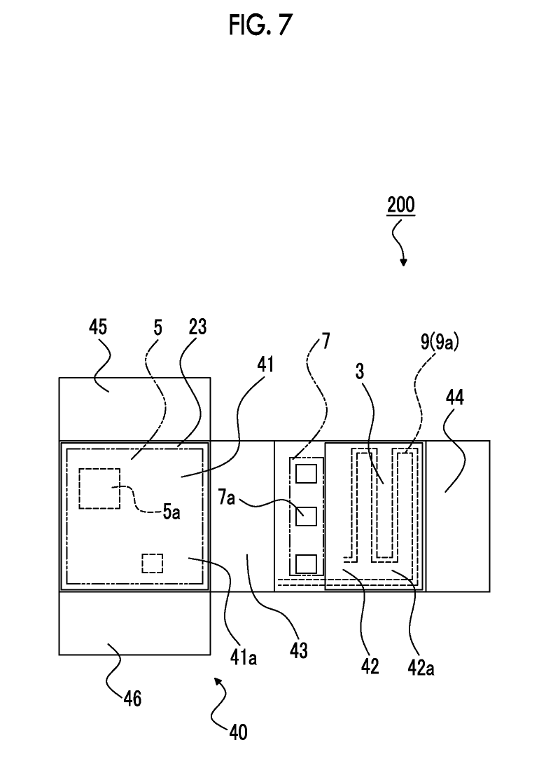

Next, a communication module 200 in a second embodiment of the present invention will be described. The communication module 200 is illustrated in FIGS. 6 and 7. FIG. 6 is a perspective view of the communication module 200. Further, FIG. 7 is a plan view of the communication module 200 in a manufacturing process.

A difference between constituent elements constituting the communication module 200 and the constituent elements constituting the communication module 100 is that a flexible board 40 of the communication module 200 is different from the flexible board 10 of the communication module 100, and other constituent elements are the same. Accordingly, the constituent elements other than the flexible board 40 constituting the communication module 200 are denoted with the same reference signs as those in the communication module 100.

As illustrated in FIG. 7, the communication module 200 includes a flexible board 40, a communication circuit 5 including a communication electronic component 5a mounted on the flexible board 40, a matching circuit 7 including a matching electronic component 7a mounted on the flexible board 40, an antenna dielectric 3, and an antenna 9 formed in the flexible board 10, similar to the communication module 100.

As illustrated in FIG. 6, the communication module 200 has a rectangular shape, is mounted on a small high-frequency device, for example, a mobile device such as a wearable terminal device, and is configured to be capable of communicating with another terminal device such as a smart phone using the antenna 9 and the communication circuit 5, similar to the communication module 100.

The flexible board 40 includes a first region 41, a second region 42, a third region 43 located between the first region 41 and the second region 42, a fourth region 44 extending to a right side of the second region 42, a fifth region 45 extending to an upper side of the first region 41, and a sixth region 46 extending to a lower side of the first region 41, as illustrated in FIG. 7. The fifth region 45 may extend to an upper side of the second region 42, and the sixth region 46 may extend to a lower side of the second region 42. The flexible board 40 is flexible, similar to the flexible board 10 of the communication module 100.

The communication electronic component 5a constituting the communication circuit 5, the matching electronic component 7a constituting the matching circuit 7, the antenna dielectric 3, the resin 23, and the antenna 9, and a method of mounting or forming these on the flexible board 40 are the same as those in the communication module 100. Therefore, description thereof is omitted.

As described above, the flexible board 40 includes six regions including the first region 41, the second region 42, the third region 43, the fourth region 44, the fifth region 45, and the sixth region 46. Accordingly, by bending portions at boundary lines of the six regions, it possible to obtain a shape of rectangular parallelepiped closed to the outside.

Accordingly, the communication module 200 is formed such that an outer shape thereof is a rectangular parallelepiped, and all of surfaces constituting the rectangular parallelepiped are covered with the flexible board 40, as illustrated in FIG. 6.

In order for the communication module 200 to be assembled in the shape of rectangular parallelepiped, a process of folding the fourth region 44 so that the fourth region 44 is connected to the first region 41 and the third region 43 and folding the fifth region 45 and the sixth region 46 so that the fifth region 45 and the sixth region 46 are respectively connected to the second region 42 and the third region 43 is only added to the method of manufacturing the communication module 100 described above.

Further, a ground pattern 47 is formed an outer surface of each of the third region 43, the fourth region 44, the fifth region 45, and the sixth region 46 among the respective regions of the flexible board 40, as illustrated in FIG. 6. In other words, the ground pattern 47 is formed on all of side surfaces of the rectangular parallelepiped constituting the communication module 200. The ground patterns 47 are connected to the respective ground patterns (not illustrated) of the communication circuit 5 and the matching circuit 7 formed on the flexible board 40, and the respective ground patterns of the communication circuit 5 and the matching circuit 7 are connected to a ground pattern of an electronic device such as a mobile device on which the communication module 100 is mounted. Although the surfaces in which the ground patterns 47 of the third region 43, the fourth region 44, the fifth region 45, and the sixth region 46 are formed are outer surfaces of the respective regions in this embodiment, the surfaces may be inner surfaces or inner layer surfaces of the respective regions (the third region 43, the fourth region 44, the fifth region 45, and the sixth region 46).

Hereinafter, effects of the present embodiment will be described.

In the communication module 100, since the antenna dielectric 3 mounted on the one surface 12a of the second region 12 of the flexible board 10 is supported by the resin 23 covering the communication circuit 5 configured on the one surface 11a of the first region 11 of the flexible board 10, a spacer is not necessary, and the communication module 100 is not damaged even when the communication module 100 is miniaturized.

Further, since the resin 23 with a wide area on the first region 11 and the antenna dielectric 3 with a relatively wide area on the second region 12 are adhered to each other such that the first region 11 and the second region 12 are adhered to each other over a wide area, it becomes difficult for the first region 11 and the second region 12 of the flexible board 10 to be peeled.

Since in the communication module 200, the outer shape is a rectangular parallelepiped, all of the surfaces constituting the rectangular parallelepiped are covered with the flexible board 40, and the ground pattern 47 is formed on all side surfaces of the rectangular parallelepiped, it is possible to enhance a shielding effect for the communication circuit 5 and the matching circuit 7.

In the method of manufacturing the communication module 100, since the communication module 100 is manufactured so that the antenna dielectric 3 mounted on the one surface 12a of the second region 12 of the flexible board 10 is supported by the resin 23 covering the communication circuit 5 configured on the one surface 11a of the first region 11 of the flexible board 10, a spacer is not necessary, and the communication module 100 is not damaged even when the communication module 100 is miniaturized.

As described above, in the communication module of the present invention, since the antenna dielectric mounted on the one surface of the second region of the flexible board is supported by the resin covering the communication circuit configured on the one surface of the first region of the flexible board, a spacer is not necessary, and the communication module is not damaged even when the communication module is miniaturized. In the method of manufacturing the communication module, since the communication module is manufactured so that the antenna dielectric mounted on the one surface of the second region of the flexible board is supported by the resin covering the communication circuit configured on the one surface of the first region of the flexible board, a spacer is not necessary, and the communication module is not damaged even when the communication module is miniaturized.

The present invention is not limited to the above embodiments, and can be variously modified and implemented without departing from the gist.

It should be understood by those skilled in the art that various modifications, combinations, sub-combinations and alterations may occur depending on design requirements and other factors insofar as they are within the scope of the appended claims of the equivalents thereof.

1. A communication module, comprising:
a flexible board having a first surface and a second surface opposite to the first surface, the flexible board including a first region, a second region, and a third region located between the first region and the second region;
an antenna including a metal pattern formed on the second surface of the second region;
a communication circuit including a communication electronic component mounted on the first surface of the first region, the communication circuit being sealed with a resin:
an antenna dielectric mounted on a portion of the first surface of the second region; and
a matching circuit including a matching electronic component mounted on another portion of the first surface of the second region, the matching circuit being configured to match the antenna with the communication circuit,
wherein the flexible board is folded at the third region such that the resin and the antenna dielectric are brought into contact with each other.

2. The communication module according to claim 1,
wherein the resin and the antenna dielectric are adhered to each other by an adhesive provided therebetween.

3. The communication module according to claim 1,
wherein the flexible board further includes a forth region extending from the second region, a fifth region extending from one side of the first region, and a sixth region extending from another side of the first region, the flexible board being folded such that an outer shape of the communication module has is a rectangular parallelepiped, all of surfaces constituting the rectangular parallelepiped are formed with the second surface of the flexible board,
and wherein the communication module further comprising:
a ground pattern formed on all of the side surfaces of the rectangular parallelepiped.

4. A method of manufacturing a communication module including a flexible board having a first surface and a second surface opposite to the first surface, the flexible board including a first region, a second region, and a third region located between the first region and the second region, the method comprising the steps of:
mounting a communication electronic component of a communication circuit on the first surface of the first region of the flexible board, and mounting an antenna dielectric and a matching electronic component on the first surface of the second region of the flexible board;
sealing the communication circuit with a resin; and
bending the flexible board at the third region such that, the resin comes into contact with the antenna dielectric, and adhering the resin to the antenna dielectric with an adhesive provided therebetween.

5. The communication module according to claim 1, wherein the resin sealing the communication circuit covers substantially the entire first surface of the first region.

6. The communication module according to claim 1,
wherein an outer shape of the communication module is a rectangular parallelepiped having a top surface, a bottom surface, and four side surfaces formed between the top and bottom surfaces,
and wherein the second surface of the flexible board forms the top surface, the bottom surface, and one of the side surfaces therebetween.

7. The method according to claim 4, further comprising:
forming an antenna including a metal pattern on the second surface of the second region of the flexible board prior to the mounting the communication electronic component.
